(19) United States
(12) Patent Application Publication
(10) Pub. No.: US 2005/0176183 A1
(43) Pub. Date: Aug. 11, 2005

(54) Method of manufacturing thin film transistor, method of manufacturing display and display

(75) Inventor: Takashi Aoki, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/043,323

(22) Filed: Jan. 27, 2005

(30) Foreign Application Priority Data
Feb. 9, 2004 (JP) 2004-032262

(51) Int. Cl. H01L 21/84; H01L 21/00

(52) U.S. Cl. 438/149

(57) ABSTRACT

A method of manufacturing a thin film transistor in which a microscopic film can be evenly formed regardless of a size of a substrate and that satisfies a low cost of manufacture and provides high performance includes applying a liquid silicon material on a predetermined region of the substrate where the thin film transistor is going to be formed, and patterning the applied liquid silicon material into a desired form. A method of manufacturing a display in which the method of manufacturing a thin film transistor is used is also provided.

### BACKGROUND

The exemplary embodiments relate to a formation method of a thin film transistor that can be applied to a liquid crystal display, an organic electroluminescence (EL) display, and the like. More particularly, the exemplary embodiments relate to a manufacturing process in which a thin film transistor substrate is formed by using a liquid silicon material and a method of manufacturing a display in which the process is used.

A thin film transistor (TFT) is used as a switch element that switches a pixel of a display. To form the TFT, a silicon film is used. The silicon film is patterned by the following process in general. First, the silicon film is formed on the whole area by a vacuum process, such as chemical vapor deposition (CVD). Then, unnecessary parts are removed by photolithography. However, this method is subjected to the following problems: (1) equipment is required to become a large scale, (2) efficiency in the use of material is low, (3) since the material is a gas, it is difficult to handle, and (4) a large amount of waste is produced.

In the related art, the display has been getting larger in size and a size of a substrate of the display exceeds 1 meter square. Forming the silicon film evenly on a substrate of this size is difficult causing technical problems as well as being costly to manufacture.

In order to address the above-mentioned problems, the related art including a method in which the liquid silicon material, such as a liquid silane compound, a high order silane, or the like is applied, and then the applied liquid silicon material is treated with heat or irradiation of ultraviolet (UV) in order to form the silicon film (for example, see Japanese Unexamined Patent Publication No. 2003-284600, Japanese Unexamined Patent Publication No. 2003-115532, Japanese Unexamined Patent Publication No. 2003-124486, Japanese Unexamined Patent Publication No. 2003-133306, Japanese Unexamined Patent Publication No. 2003-171556 and Japanese Unexamined Patent Publication No. 2003-313299). In related art, it is easy to handle the material since it is liquid. Furthermore, the silicon film can be formed at low cost because large equipment is not required.

Japanese Unexamined Patent Publication No. 2001-179167 discloses a method of forming the silicon film in which a material solution is directly patterned by an ink-jet method. Specifically, the number of the photolithography process and a waste of the material can be reduced with such method. However, miniaturization of devices have been advanced recently and it is difficult to form a thin film transistor device with a required accuracy by only the direct patterning of the ink-jet method because the ink-jet method has an accuracy, at best, of about a few dozen microns.

### SUMMARY

As described above, in the related art, an accuracy of the patterning by the ink-jet method or a dispensing method is about 10 micron at best even when a bank or a hydrophilic/lipophilic pattern is supplementally used. However, the size of the thin film transistor is getting smaller and smaller with a trend towards a display with high resolution and high-luminance. Formation of a device in a micron size order is demanded.

In view of the above-mentioned problems, the exemplary embodiments provide a method of manufacturing a thin film transistor in which a microscopic film can be evenly formed regardless of a size of a substrate that satisfies both low cost and high performance needs.

Furthermore, the exemplary embodiments also provide a method of manufacturing a display that has an advantage of low costs and can provide a high performance display regardless of the size of the display.

In order to address or solve the above noted and/or other problems, a method of manufacturing a thin film transistor of the exemplary embodiments include applying a liquid silicon material on a predetermined region of a substrate where the thin film transistor is going to be formed, and patterning the applied liquid silicon material into a desired form.

Exemplary embodiments also provide the following features.

In the method of manufacturing a thin film transistor, the liquid silicon material may be a liquid including a silane compound and/or a high-order silane.

In the method of manufacturing a thin film transistor, the liquid silicon material may be a liquid including a silane compound and/or a high-order silane and a compound that includes an element in group IIIb of the periodic table or an element in group Vb of the periodic table.

In the method of manufacturing a thin film transistor, the liquid silicon material may be applied by an ink-jet method or a dispensing method.

In the method of manufacturing a thin film transistor, the applied liquid silicon material may be patterned by using a resist as a mask and the resist may be applied by the ink-jet method.

In the method of manufacturing a thin film transistor, the predetermined region may be a peripheral area including a channel region of the thin film transistor.

In the method of manufacturing a thin film transistor, the predetermined region may be a peripheral area including a source and drain region of the thin film transistor.

In order to address or solve the above noted and other problems, the exemplary embodiments also provide the following features:

A method of manufacturing a display of the exemplary embodiments includes the above noted method of manufacturing a thin film transistor.

A display of the exemplary embodiments may be-obtained by the above noted method of manufacturing a display.

According to the method of manufacturing a thin film transistor of the exemplary embodiments, a microscopic film can be evenly formed regardless of a size of a substrate and while maintaining low manufacturing and high performance.

Furthermore, according to the method of manufacturing a display of the exemplary embodiments, the thin film transistor can be formed with a low manufacturing cost regardless of a size of a substrate and a variation in quality of the thin film transistors can be reduced, minimized or eliminated. Therefore, a high-resolution display can be manufactured.

### BRIEF DESCRIPTION OF THE DRAWINGS

FIG. 1 is a schematic showing a step of a method of manufacturing a thin film transistor in an exemplary embodiment;

FIG. 2 is a schematic showing a step of a related art manufacturing method of a thin film transistor in an exemplary embodiment;

FIGS. 3(1) through 3(8) are schematics showing processes of manufacturing a thin film transistor substrate according to a first exemplary embodiment;

FIG. 4 is a cross-sectional schematic taken along the line A-A in FIG. 3(8) in, an exemplary embodiment;

FIGS. 5(1) through 5(7) are schematics (plan views and sectional views) showing an example of a process to which the method of manufacturing a thin film transistor in an exemplary embodiment is applied; and

FIG. 6 is a schematic of a thin film transistor obtained by a method of manufacturing a thin film transistor in an exemplary embodiment.

### DETAILED DESCRIPTION OF EMBODIMENTS

A method of manufacturing a thin film transistor will be described based on the exemplary embodiments.

As described above, the method of manufacturing a thin film transistor according to the exemplary embodiments includes applying a liquid silicon material on a predetermined area of a substrate where the thin film transistor is going to be formed, and patterning the applied silicon material into a desired shape.

In this way, a microscopic film can be evenly formed on a substrate regardless of a size or a position of the substrate like a silicon film formed by a commonly used CVD method. Furthermore, the thin film transistor that satisfies a low cost of manufacture and provides high performance can be formed according to the exemplary embodiments.

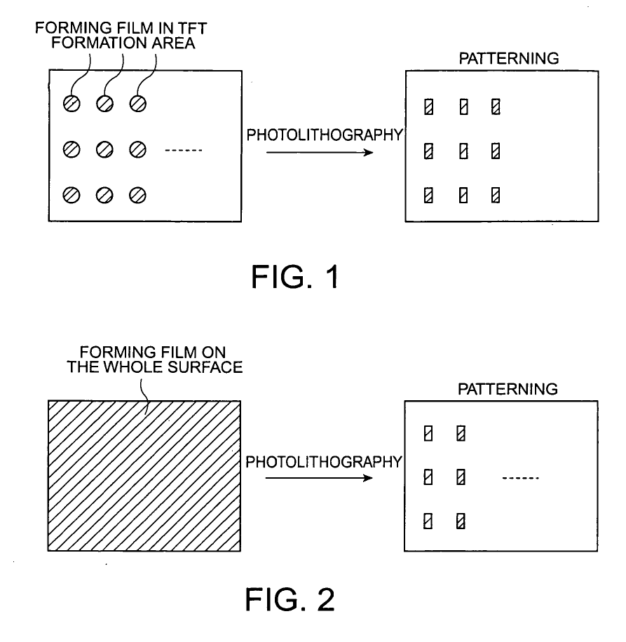

In an exemplary embodiment, as shown in FIG. 1, silicon film formation is conducted by applying the liquid silicon material on a predetermined area of the substrate, where the thin film transistor (TFT) is going to be formed. Then, a microscopic patterning, in which the applied silicon material is patterned into a desired shape, is conducted by photolithography. This manufacturing method uses less area to form a film compared to a case where the film is formed on the whole surface of the substrate. Then, the photolithography is performed as shown in FIG. 2. In this way, the manufacturing method according to the exemplary embodiments uses a smaller amount of material and the amount of wastes produced after a photo-etching is significantly reduced or decreased. This leads to lower cost of manufacturing.

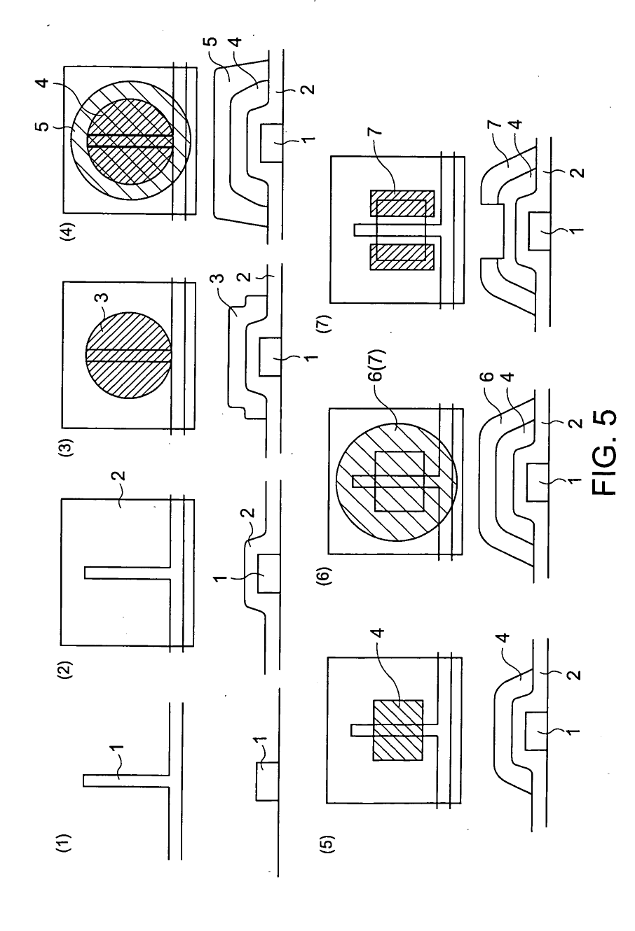

An example of a process to which the method of manufacturing a thin film transistor according to the exemplary embodiments is applied as shown in FIGS. 5(1)-5(7). Each of FIGS. 5(1)-5(7) includes a plan view to show a portion placed under (inside) the surface (an upper figure) visible and a sectional view of the plan view (a lower figure).

The steps of each of FIGS. 5(1)-5(7) are discussed below.

First, as shown in FIG. 5(1), a gate electrode 1 that is provided in a plural number is formed on the substrate. Then, as shown in FIG. 5(2), a gate insulating film 2 is broadly formed on the each gate electrode 1 so as to cover the gate electrode 1. And then, as shown in FIG. 5(3), a droplet 3, which is the liquid silicon material, is applied to the substrate on which the gate electrode 1 and the gate insulating film 2 are formed so as to cover a peripheral part that includes an area right above the gate electrode 1 by the ink-jet method or the dispensing method.

As shown in FIG. 5(3), the substrate on which the droplet 3 of the liquid silicon material is provided is obtained by the step of applying the liquid silicon material. Then, the substrate is calcined under the conditions of an appropriate temperature, pressure and time in order to form the film. If necessary, a light/thermal treatment is performed to the film and a silicon film 4 is formed. Such silicon film 4 will become a channel layer of the thin film transistor.

As shown in FIG. 5(4), the photolithography is conducted by first applying a resist solution 5 on the silicon film 4 by an ink-jet method or a spin-coat method. Second, a pre-bake is performed, followed by exposure. Finally, a post-bake and development are performed. Next, as shown in FIG. 5(5), the silicon film 4 is patterned by etching.

As shown in FIG. 5(6), a droplet 6 including a dopant (which is described later) and the liquid silicon material is applied to the peripheral part that includes the area right above the gate electrode 1 by the ink-jet method or the dispensing method. Then calcination is performed under an appropriate condition and then a dope-silicon film 7 is formed.

Like the steps shown in FIG. 5(4) and FIG. 5(5), application of the resist solution, the pre-bake, the exposure and the development are performed as a photolithography process. Then the dope-silicon film 7 is patterned by etching the dope-silicon film 7 as shown in FIG. 5(7).

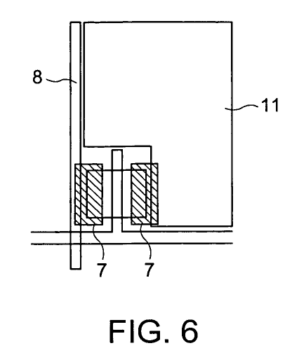

Next, after the silicon film 4 and the dope-silicon film 7 are annealed, the thin film transistor is formed by forming a source wiring 8, a transparent electrode 11 and the like on the dope-silicon film 7 as shown in FIG. 6.

In the application step of the liquid silicon material according to the exemplary embodiments, the droplet of the liquid silicon material is applied to the predetermined area of the substrate where the thin film transistor is formed (an area where the transistor is decided to be formed in advance). In the predetermined area where the thin film transistor is formed, the channel region of the thin film transistor that is going to be formed is completely or substantially covered. For example, the application may be performed in the way shown in FIG. 5(3) or FIG. 5(6).

As the liquid silicon material used in the exemplary embodiments, a liquid including a silane compound and/or a high-order silane can be preferably used. For example, this liquid is used in the step shown in FIG. 5(3).

As the liquid silicon material, a silane compound and/or a high-order silane or those solution in which a dopant is added can also be used. This solution is exemplified in the step shown in FIG. 5(6).

Here, the “dopant” referrers to a substance that is contained in the liquid silicon material and that can be formed into an n-type or p-type dope silicon film by light induced activation. As such substance, a compound that includes an element in the group IIIb or Vb of the periodic table such as boron and arsenic can be used. To be more specific, examples of such compound includes boron, yellow phosphor, decaborane, and material mentioned in Japanese Unexamined Patent Publication No. 2000-31066.

As the above-mentioned silane compound, for example, a substance represented by SiₙXₘ (where n and m are positive integers, with n is more than 2 and m is more than 3 and X is a substituent of hydrogen atom and/or halogen atom and the like) can be named.

As the liquid silicon material, high-order silane compounds described in Japanese Unexamined Patent Publication No. 2003-313299 or a composition that includes a high-order silane made from a light-polymerized silane compound by being exposed to ultraviolet can be used. Another composition that includes a high-order silane made in such a way that a solution including the above-mentioned silane compound is exposed to ultraviolet and polymerized can also be used.

Such a high-order silane is produced by a light-polymerization of the silane compound or the silane compound solution with exposure to ultraviolet. A molecular weight of the high-order silane is much larger (up to one having a molecular weight of 1800 has been identified) than that of a normal silane compound which is made by a conventional method (for example, a molecular weight of Si₆H₁₄ is 182). Such a high-order silane having a heavy molecular weight has a boiling point which is higher than a decomposition point. This means that a film can be formed before the silane evaporates and disappears. Therefore, the silicon film can be efficiently formed compared to the conventional silicon film forming method. When such high-order silane is actually heated, the silane is decomposed before it reaches the boiling point. Therefore, the boiling point which is higher than the decomposition point cannot be experimentally decided. However, the boiling point here means a theoretical value at the atmospheric pressure which is estimated from a temperature dependence of vapor pressure and theoretical calculation.

Furthermore, with such a liquid silicon material containing the above-described high-order silane, it is not necessary to hastily heat the material at high temperature before it evaporates because the boiling point of the high-order silane is higher than that of the decomposition point. In other words, it is possible to perform such processes as heating the material with slow rising tempo of temperature and heating the material at a relatively low temperature under reduced pressure. This means that a bonding speed of silicon at the time of the silicon layer formation can be controlled. In addition, solvent in the silicon film which will deteriorate a quality of the silicon can be efficiently reduced or minimized compared to the method of the related art. This is possible by maintaining higher temperature than the boiling point of the solvent but not as high as a temperature at which the silicon film is formed.

As the light-polymerized high-order silane, its boiling point should be higher than that of the decomposition point as described above. Such high-order silane having the high boiling point than the decomposition point can be easily obtained by selecting specific silane compounds which will be described later as precursor, and selecting a specific wave length of the ultraviolet to which the silane compound is exposed, a way and a time of the exposure, an energy of the exposure and a refining process of the solvent and the silane compound after the exposure.

A molecular weight distribution of the high-order silane can be controlled by changing a time, a level and a way of exposure to the ultraviolet. Moreover, a high-order silane with a desired molecular weight can be extracted by performing separation and refinement using a common polymer refining method such as Gel Permeation Chromatography (GPC) after the exposure to the ultraviolet. The refinement can be conducted by making use of a difference in solubility between high-order silane compounds with different molecular weights. The refinement can also be conducted by fractional distillation making use of a difference in a boiling point between high-order silane compounds with different molecular weights under atmospheric pressure or reduced pressure. In these ways, a fine silicon film with less variation in quality can be obtained by controlling the molecular weight of the high-order silane in the liquid material.

The boiling point of the high-order silane becomes higher in proportion to the molecular weight. Furthermore, the solubility in the solvent decreases as the molecular weight becomes larger. For this reason, the light-polymerized high-order silane sometimes cannot dissolve enough and appears again depending on a condition of the ultraviolet exposure. In this case, the high-order silane will be refined by removing insoluble elements by percolation using a micro-filter and the like.

The time of the exposure to the ultraviolet is preferably from 0.1 sec to 120 minutes, particularly 1-30 minutes, in order to obtain the desired high-order silane with the desired molecular weight distribution.

A viscosity and a surface tension of the liquid material containing the silane compound which is a precursor of the high-order silane can be easily controlled by adjusting the solvent or the above-mentioned method of controlling the molecular weight distribution of the high-order silane. When the silicon film is formed from a liquid material, there is an advantage in that patterning can be performed by the ink-jet method. When this liquid discharging method is employed to pattern silicon, there is an advantage in that the viscosity and the surface tension can be easily controlled by adjusting the solvent as described above.

The above-mentioned silane compound, which is the precursor of the high-order silane, is not especially limited as long as it is polymerized by the exposure to ultraviolet. For example, the above-mentioned substance represented by SiₙXₘ (where n and m are positive integers, with n is more than 2 and m is more than 3 and X is a substituent of hydrogen atom and/or halogen atom and the like) can be used as the silane compound.

As such silane compounds, a cyclic silane compound represented by SiₙX₂ₙ (where n is positive integers and more than 2 and X is hydrogen atom and/or halogen atom and the like), a silane compound having more than one cyclic structure represented by SiₙX₂ₙ₋₂ (where n is positive integers and more than 3 and X is hydrogen atom and/or halogen atom), silicon hydride having at least one cyclic structure and its derivative substitution of halogen and all other silane compounds that are polymerized by the exposure to the ultraviolet can be used.

As such a silane compound having one cyclic structure, cyclotrisilane, cyclotetrasilane, cyclopentasilane, cyclohexasilane, cycloheptasilane and the like can be named. As a silane compound having two cyclic structures, 1,1′-bicyclobutasilane, 1,1′-bicyclopentasilane, 1,1′-bicyclohexasilane, 1,1′-bicycloheptasilane, 1,1′-cyclobutasilylcyclopentasilane, 1,1′-cyclobutasilylcyclohexasilane, 1,1′-cyclobutasilylcycloheptasilane, 1,1′-cyclopentasilylcyclohexasilane, 1,1′-cyclopentasilylcycloheptasilane, 1,1′-cyclohexasilylcycloheptasilane, spiro[2.2]pentasilane, spiro[3.3]heptasilane, spiro[4.4]nonasilane, spiro[4.5]decasilane, spiro[4.6]undecasilane, spiro[5.5]undecasilane, spiro[5.6]undecasilane, spiro[6.6]tridecasilane and other silicide in which skeletal hydrogen atom is partially replaced by SiH₃ group or halogen atom can be used. These compounds may be used in mixture of more than one compound.

Especially, a silane compounds having at least one cyclic structure is desirable because it is highly reactive to light and efficiently polymerized by light. Particularly, a silane compound represented by SiₙX₂ₙ (where n is positive integers and more than 2 and X is hydrogen atom and/or halogen atom such as fluorine atom, chlorine atom, bromine atom and iodine atom) such as cyclotetrasilane, cyclopentasilane, cyclohexasilane and cycloheptasilane may be advantageous because synthesis and refinement is easy in addition to the above-mentioned reason.

As the solvent used for the liquid material in the exemplary embodiments is not particularly limited as long as it can solve the high-order silane which is made from the above-mentioned silane compound or the light-polymerized silane compound and it does not react to the silane compound or the high-order silane. A vapor pressure of such solvent at room temperature is usually 0.001-200 mmHg.

This is because when the solvent with the vapor pressure of more than 200 mmHg is used to form a film by coating, the solvent will be evaporated first and this makes it difficult to form a fine film. In contrast, when the solvent with the vapor pressure of lower than 0.001 mmHg is used to form a film by coating, it will take a long time to dry and the solvent is likely to remain in the coating film of the silane compound or the high-order silane. This makes it difficult to obtain a fine silicon layer even after a thermal treatment or/ and a light exposure treatment of a post-process is performed.

Furthermore, it is desirable for the solvent to have a higher boiling point at the normal pressure than the room temperature and the boiling point to be lower than 250-300° C., which is the decomposition point of the silane compound with large molecular weight or the high-order silane. With the solvent having the lower boiling point than the decomposition point of the high-order silane, when the liquid material is applied and heated, only the solvent can be selectively removed without decomposing the high-order silane. This can prevent the solvent from remaining in the silicon layer and a fine film can be obtained.

As the solvent used in the liquid material, in other words, the solvent in the silane compound solution, the solvent in the silane compound solution as the precursor before the ultraviolet exposure in the case where the high-order silane is formed or the solvent in the high-order silane compound solution after the ultraviolet exposure, a hydrocarbon-like solvent such as n- hexane, n-heptane, n-octane, n-decane, dicyclopentane, benzene, toluene, xylene, durene, indene, tetrahydronaphthalene, decahydronaphthalene and squalene can be used. An ether-kind solvent such as dipropylether, ethyleneglycol-dimethylether, ethyleneglycol-diethylether, ethyleneglycol-methylethylether, diethyleneglycol-dimethylether, diethyleneglycol-diethylether, diethyleneglycol-methylethylether, tetrahydrofuran, tetrahydropyran, 1,2-dimethoxyethane, bis(2-methoxyethyl)ether and p-dioxane can also be used as the solvent. A polar solvent such as propylenecarbonate, γ-butyrolactone, N-methyl-2-pyrrolidone, dimethylformamide, acetonitrile and dimethylsulfoxide can also be used as the solvent.

The liquid silicon material used in the manufacturing method according to the exemplary embodiments is a solution containing the silane compound or the high-order silane obtained by the above-described method as a solute. The solvent used in the manufacturing method according to the exemplary embodiments is described above. A concentration of the solute is usually about 1-80% by weight and it can be adjusted depending on a thickness of the desired silicon film. When the concentration of the solute is more than 80% by weight, the silane compound with a large molecular weight or the high-order silane is likely to be separated out and it makes it difficult to obtain a uniform film.

The liquid material to form the silicon film has usually a viscosity of 1-100 m Pa.s. The viscosity can be changed according to application equipment or a desired film thickness. However, when the viscosity is smaller than 1 m Pa.s, the coating becomes difficult and when the viscosity is larger than 100 m Pa.s, it gets difficult to obtain the uniform film.

If it is necessary, a small amount of a surface tension regulator, such as fluorinated, silicon-like and nonionic regulator can be added to the liquid silicon material as long as it will not impair a necessary function of the liquid silicon material. The nonionic surface tension regulator improves a wettability of the solution when the solution is applied and a leveling property of the applied film. The nonionic surface tension regulator also helps to prevent bubbles from being generated like rash in the film.

After the liquid silicon material is applied to a substrate, if it is necessary, the thermal treatment and/or the light process can be performed in order to induce a thermal decomposition of the silane compound or the high-order silane compound and form an amorphous silicon film or a polysilicon film.

As the substrate used in the exemplary embodiments, various kinds of material can be employed. For example, a flexible substrate (film) such as a film form of polyethylene terephthalate (PET), polybutylene terephthalate (PBT) and the like can be used as well as an inflexible substrate, such as glass.

To apply the liquid silicon material to the substrate, a common liquid application machine such as an ink-jet device, a dispenser, a micro dispenser and the like may be used. In other words, the ink-jet method or the dispensing method is desirable. For example, the application method shown in FIG. 5(3) and FIG. 5(6) can be employed. When the silane compound or the high-order silane is used as the liquid silicon material, the whole process may be advantageously carried out with no water and oxygen since the silane compound and the high-order silane easily react to water and oxygen and they will be denatured. Therefore, an atmosphere of the whole process with an inert gas such as nitrogen, helium and argon is desired. Moreover, a reducing gas such as hydrogen may be advantageously mixed into the atmosphere according to need. Furthermore, it is desired that water and oxygen in the solvent and additive is removed.

The photolithography process in the exemplary embodiments is not particularly limited, but a photolithography which is commonly used in a formation of the thin film transistor can be performed. For example, a method of patterning into an island shape, which is described in Japanese Unexamined Patent Publication No. 6-102531, can be applied.

Particularly, a photolithography including a resist application step by the ink-get method, a step of pre-bake and a step of exposure and development can be preferably performed. For example, the photolithography process shown in FIG. 5(4) or FIG. 5(7) can be performed.

Almost all the processes that are performed in the common manufacturing method of the thin film transistor can be applied to the method of manufacturing a thin film transistor according to the exemplary embodiments other than the above-mentioned liquid silicon material application process and the above-mentioned photolithography process.

With the above-described thin film transistor manufacturing process, the following favorable effect can be achieved. The liquid application method can form a uniform silicon film on a large substrate because the liquid application does not have any dependency with a place where the liquid is applied. Moreover, a miniaturization of the silicon film is possible by performing a photo-etching. In this way, a thin film transistor which can satisfy both of high performance and low cost can be manufactured.

According to the exemplary embodiments, a method of manufacturing a display using the above-described method of manufacturing a thin film transistor can be provided. According to this method, an active matrix type display such as a liquid crystal display and an organic electroluminescent (EL) display having advantages of low cost and high-performance regardless of a size of the display can be obtained.

Although the present invention will be now described in detail by way of a specific exemplary embodiment, the exemplary embodiments are not limited to the specific exemplary embodiment.

### First Specific Embodiment

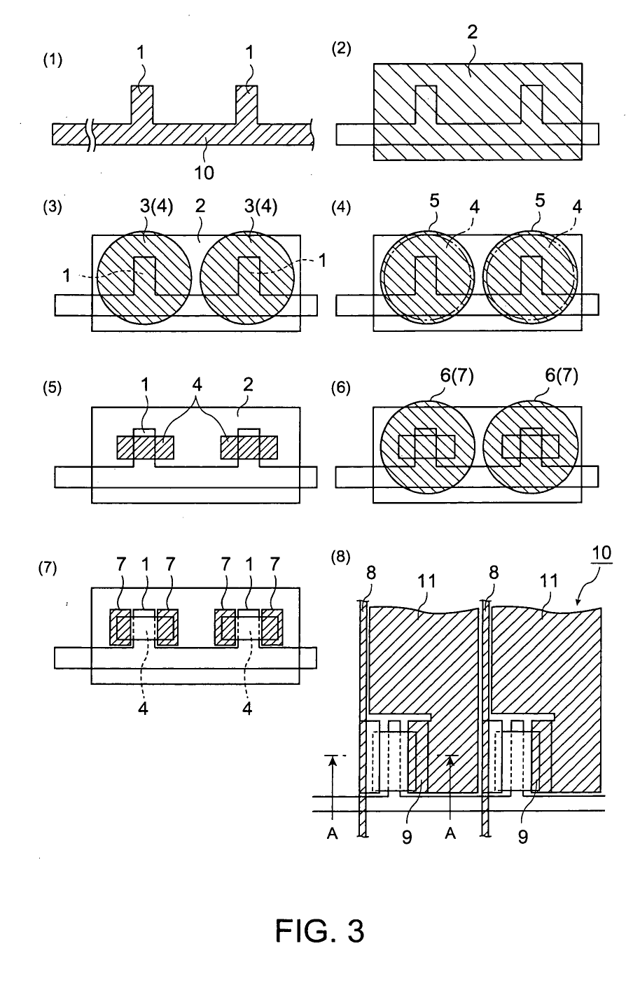

A manufacturing process of a thin film transistor substrate according to a first specific exemplary embodiment is shown in FIGS. 3(1)-3(8). Each of FIGS. 3(1)-3(8) is a plan view showing things placed under (inside) the surface as visible.

Tantalum (Ta) (metal) is sputtered on the whole surface of a glass substrate (not shown in the figure). Then, a gate electrode wiring 1a to which each gate electrode 1 is coupled is formed by the photo-etching (FIG. 3(1)). The gate insulating film 2 made of silicon oxide (SiO₂) is formed on the gate electrode wiring by tetraethoxy silane chemical vapor deposition (TEOS-CVD) (FIG. 3(2)).

Next, a solution (solution A) is confected by solving hexasilane 3% by weight in tetradecane and the solution A is applied toward each gate electrode 1 by the ink-jet method. In this way, a substrate on which the droplet 3 made of the solution A is provided is formed (FIG. 3(3)). The substrate is heated to 100° C. and pressure is reduced to 10⁻³ Torr. Then, the substrate is calcined at 400° C. for 30 minutes and the silicon film 4 which is going to be the channel layer is formed (FIG. 3(3)).

Next, a resist solution 5 is applied on the silicon film 4 by the ink-jet method and the substrate is pre-baked at 130° C. for 10 minutes. Then, exposure is performed by using an aligner (FIG. 3(4)). The silicon film 4 is patterned by post-bake and development followed by etching (FIG. 3(5)).

Next, solution B is confected by adding decaborane of 0.1% by weight to the above-mentioned solution A. The solution B is applied to a part which lies directly above the gate electrode 1 by the ink-jet method in the same way as the application of the solution A. In this way, the substrate on which the droplet 6 made of the solution B is provided is formed (FIG. 3(6)). Then, the substrate is calcined at 400° C. for 30 minutes. and the dope-silicon film 7 is formed (FIG. 3(6)).

Furthermore, in the same way as the above-described process, the dope-silicon film 7 is patterned by performing the application of the resist solution by the ink-jet method, the pre-bake, the exposure, the development and the etching of the dope-silicon film (FIG. 3(7)). The silicon film (the silicon film 4 and the dope-silicon film 7) on the substrate is annealed by an excimer laser at a wave length of 308 nm. This improves a crystalline property of the channel part and a source-drain region.

Then, the source wiring 8 made of a metal particle ink, a drain wiring 9 and the transparent electrode 11 made of an indium tin oxide (ITO) ink are formed by the ink-jet method. Finally, a thin film transistor substrate 10 for the liquid crystal display is made (FIG. 3(8)).

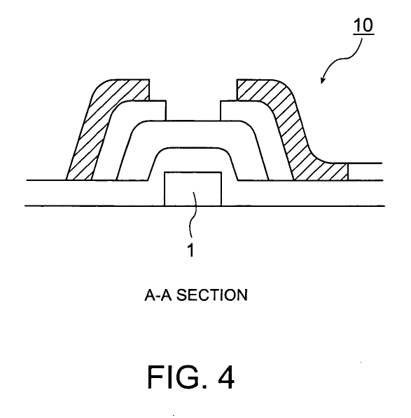

FIG. 4 is a sectional view of the thin film transistor substrate 10 formed by the manufacturing method described in the first specific exemplary embodiment around the gate electrode 1 (sectional view of a part of FIG. 3(8) along the line A-A). As shown in FIG. 4, the thin film transistor substrate 10 includes the gate electrode 1 made of Ta, the gate insulating film 2 made of SiO₂ on the gate electrode 1, the silicon film 4 (channel) formed on the gate insulating film 2 and directly above the gate electrode 1, the dope-silicon film 7, the source wiring 8, the drain wiring 9 and the transparent electrode 11.

Although the gate electrode is placed in an upper position in the first specific exemplary embodiment, the manufacturing method of the exemplary embodiments can also be applied to a thin film transistor in which the gate electrode is placed in a lower position (bottom gate type) (see Patent Publication WO97/13177, Japanese Unexamined Patent Publication No. 2001-53283 and the like).

### EXEMPLARY INDUSTRIAL APPLICABILITY

The exemplary embodiments can be applied to a method of manufacturing a thin film transistor which can form a uniform and refined film regardless of the size of the substrate and can achieve lowering cost and a high performance. The exemplary embodiments can also be applied to a method of manufacturing a display which has a high performance regardless of the size of the display and has advantage in a cost aspect.

1. A method of manufacturing a thin film transistor, comprising:
applying a liquid silicon material on a predetermined region of a substrate corresponding to a location of formation of the thin film transistor; and
patterning the applied liquid silicon material into a desired form.

2. The method of manufacturing a thin film transistor according to claim 1, the liquid silicon material being a liquid including at least one of a silane compound and a high-order silane.

3. The method of manufacturing a thin film transistor according to claim 1, the liquid silicon material being a liquid including at least one of a silane compound and a high-order silane, and a compound that includes an element in group IIIb of the periodic table or an element in group Vb of the periodic table.

4. The method of manufacturing a thin film transistor according to claim 1, the applying a liquid silicon material including at least one of an ink-jet method and a dispensing method.

5. The method of manufacturing a thin film transistor according to claim 1, the patterning the applied liquid silicon material including using a resist as a mask, and applying the resist by an ink-jet method.

6. The method of manufacturing a thin film transistor according to claim 1, the predetermined region being a peripheral area including a channel region of the thin film transistor.

7. The method of manufacturing a thin film transistor according to claim 1, the predetermined region being a peripheral area including a source and drain region of the thin film transistor.

8. A method of manufacturing a display, comprising:
the method of manufacturing a thin film transistor according to claim 1.

9. A display obtained by the method of manufacturing a display according to claim 8.
